(19) United States
(12) Patent Application Publication
(10) Pub. No.: US 2015/0040973 A1
(43) Pub. Date: Feb. 12, 2015

(54) LIGHT TRANSMISSION TYPE TWO-SIDED SOLAR CELL

(71) Applicant: Samsung Electronics Co., Ltd., Suwon-si (KR)

(72) Inventors: Yeong Suk CHOI, Suwon-si (KR); Jong Hwan PARK, Yongin-si (KR)

(73) Assignee: Samsung Electronics Co., Ltd., Suwon-Si (KR)

(21) Appl. No.: 14/176,243

(22) Filed: Feb. 10, 2014

(30) Foreign Application Priority Data
Aug. 12, 2013 (KR) 10-2013-0095584

(51) Int. Cl. H01L 31/068

(52) U.S. Cl. CPC H01L 31/0684
USPC 136/255

(57) ABSTRACT

A light transmission type of two-sided solar cell includes a front sub-cell on a first side of the transparent substrate, the front sub-cell including a first electrode, a first photoactive layer, and a second electrode, and a rear sub-cell on a second side of the transparent substrate, the rear sub-cell including a third electrode, a second photoactive layer, and a fourth electrode, at least one of the third electrode and the fourth electrode being a reflection electrode, the reflection electrode having an area of about 50 to about 95% relative to an area of the second photoactive layer.

### CROSS REFERENCE TO RELATED APPLICATION

This application claims priority to and the benefit of Korean Patent Application No. 10-2013-0095584 filed in the Korean Intellectual Property Office on Aug. 12, 2013, the entire contents of which are incorporated herein by reference.

### BACKGROUND

1. Field

Some example embodiments relate to a light transmission type two-sided solar cell.

2. Description of the Related Art

A solar cell is a photoelectric conversion device that transforms solar energy into electrical energy, and has attracted much attention as an infinite but pollution-free next generation energy source.

A solar cell includes a photoactive layer including p-type and n-type semiconductors and produces electrical energy by transferring electrons and holes to the n-type and p-type semiconductors, respectively, and then collecting the electrons and holes in each electrode when an electron-hole pair (EHP) is produced by solar light energy absorbed in a photoactive layer inside the semiconductors.

On the other hand, a solar cell having various additional functions other than a function of generating electrical energy is being researched. For example, a light transmission type solar cell may generate electrical energy and simultaneously transmit solar light and thus adjust inflowing light from the outside when installed on a window or an exterior building wall.

However, efficiency of the solar cell can deteriorate, since the amount of light absorbed in a photoactive layer is in general decreased when light transmission of the solar cell is increased.

### SUMMARY

Some example embodiments provide a light transmission type of solar cell with adjusted light transmission as well as securing absorbance.

According to an example embodiment, a light transmission type of two-sided solar cell includes a front sub-cell on a first side of a transparent substrate, the front sub-cell including a first electrode, a first photoactive layer, and a second electrode, and a rear sub-cell on a second side of the transparent substrate, the rear sub-cell including a third electrode, a second photoactive layer, and a fourth electrode, at least one of the third electrode and the fourth electrode being a reflection electrode, the reflection electrode having an area of about 50 to about 95% relative to an area of the second photoactive layer.

A total absorbance of the solar cell may be a sum of absorbance of the first photoactive layer and absorbance of the second photoactive layer, and a total absorbance of the solar cell may be higher than absorbance of a non-light transmission single sub-cell including one of the first photoactive layer and the second photoactive layer.

A light transmittance of the solar cell may be about 5% to about 50%. A total area of one of the first electrode and the second electrode may be less than or equal to about 20% relative to a total area of the first photoactive layer.

The first electrode and the second electrode may comprise a plurality of finger electrodes, respectively. A width of the finger electrodes of the first electrode may be less than or equal to about 2000 μm, and gaps between adjacent finger electrodes of the first electrode may be less than or equal to about 5000 μm. A width of the finger electrodes of the second electrode may be less than or equal to about 2000 μm, and gaps between adjacent finger electrodes of the second electrode may be less than or equal to about 5000 μm.

Each of the third electrode and the fourth electrode may comprise a plurality of finger electrodes. A width of the finger electrodes of the third electrode may be less than or equal to about 2000 μm, and gaps between adjacent finger electrodes of the third electrode may be less than or equal to about 5000 μm.

Each of the first photoactive layer and the second photoactive layer may comprise one of silicon, a compound semiconductor, an organic semiconductor, a dye, quantum dots, and a combination thereof. The first photoactive layer may absorb light having a longer wavelength range than the second photoactive layer.

The light transmission type two-sided solar cell may further include an auxiliary layer between at least one of the first electrode and the first photoactive layer, the second electrode and the first photoactive layer, the third electrode and the second photoactive layer, and the fourth electrode and the second photoactive layer.

### BRIEF DESCRIPTION OF THE DRAWINGS

These and/or other aspects will become apparent and more readily appreciated from the following description of the embodiments, taken in conjunction with the accompanying drawings in which:

FIG. 1 and FIG. 2 are top plan views of a front sub-cell and a rear sub-cell of a solar cell according to an example embodiment, respectively, and

FIG. 3 is a cross-sectional view of a solar cell according to an example embodiment.

### DETAILED DESCRIPTION

Example embodiments will hereinafter be described in detail referring to the following drawings, and may be more easily performed by those who have common knowledge in the related art. However, these embodiments are only examples, and the inventive concepts are not limited thereto.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, a solar light-receiving side is a front side and an opposite side of the front side is a rear side.

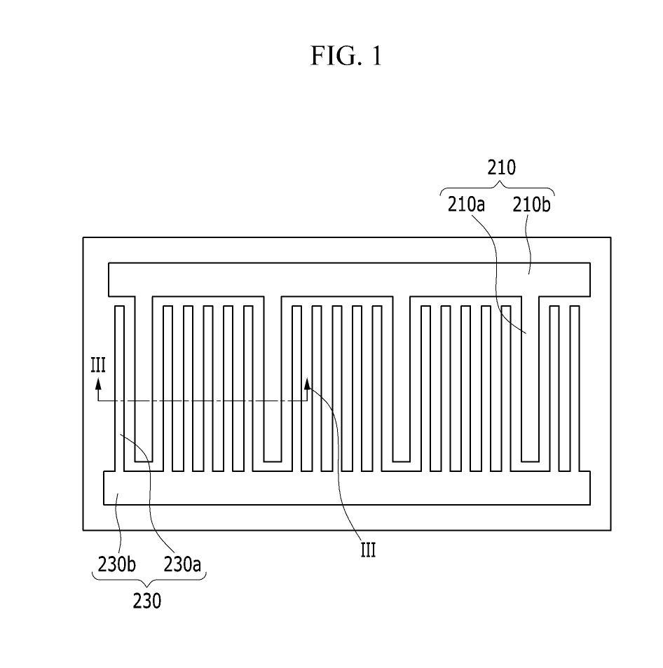

Referring to FIGS. 1 to 3, a solar cell according to an example embodiment is illustrated.

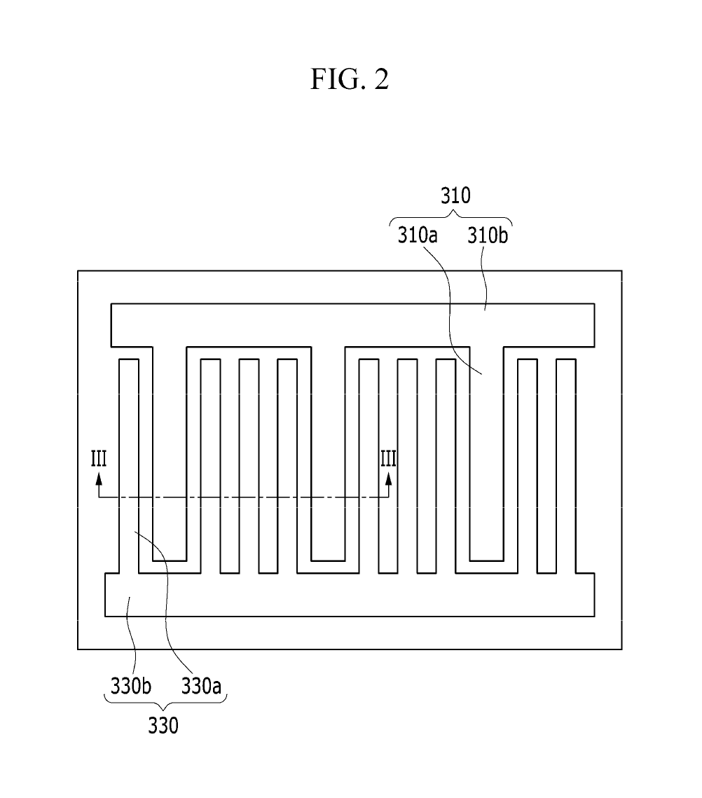

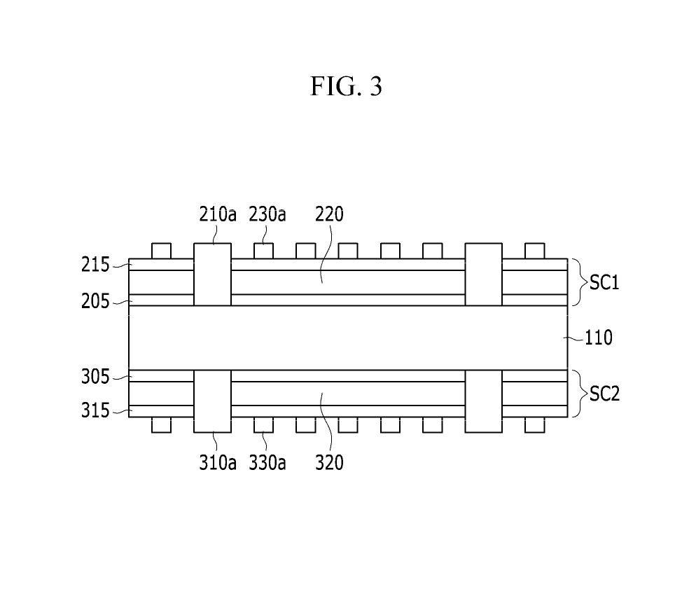

FIGS. 1 and 2 are top plan views of a front sub-cell and a rear sub-cell of a solar cell according to an example embodiment, respectively, and FIG. 3 is a cross-sectional view of a solar cell according to an example embodiment.

A solar cell according to an example embodiment includes a transparent substrate 110, a front sub-cell SC1 positioned on a first side of the transparent substrate 110, and a rear sub-cell SC2 positioned on a second side of transparent electrode 110.

The transparent substrate 110 may be made of a light transmittance material, and the light transmittance material may include, for example, an inorganic material such as glass or an organic material such as polycarbonate, polymethyl methacrylate, polyethylene terephthalate, polyethylene naphthalate, polyamide, polyether sulfone, or a combination thereof.

The front sub-cell SC1 is positioned at a solar light incidence side, and includes a first electrode 210, a first photoactive layer 220, and a second electrode 230.

One of the first electrode 210 and the second electrode 230 may be an anode and the other may be a cathode.

The first electrode 210 and second electrode 230 may be transparent electrodes, semitransparent electrodes, or opaque electrodes, the transparent electrode or semitransparent electrode may be, for example, a conductive oxide such as indium tin oxide (ITO), indium doped zinc oxide (IZO), tin oxide (SnO₂), aluminum doped zinc oxide (AZO), gallium doped zinc oxide (GZO), and the like, a conductive carbon composite such as carbon nanotubes (CNT) or graphene, a metal, or a combination thereof in a thin thickness of several to tens of nanometers, and the opaque electrode may be a metal electrode such as aluminum (Al), silver (Ag), copper (Cu), gold (Au), lithium (Li), and alloys thereof.

The first electrode 210 and second electrode 230 may be metal electrodes designed in a form of, for example, a grid pattern. The metal electrode having the grid pattern may be favorable in terms of light shadowing loss and a sheet resistance.

The first electrode 210 may include, for example, a plurality of finger electrodes 210a and a bus bar electrode 210b connecting the same. The plurality of finger electrodes 210a may be aligned in one direction, without limitation.

Herein, the first electrode 210 may be formed in a size to appropriately control a light shadowing loss and sheet resistance having a trade-off relationship. For example, the first electrode 210 may be designed to have a total area of less than or equal to about 20% relative to the total area of the first photoactive layer 220 and to have power loss of less than or equal to about 20%. For another example, the total area of the first electrode 210 may be about 1 to about 20% relative to the total area of the first photoactive layer 220, and the power loss may be about 0.1 to about 20%. For example, a width of each finger electrode 210a of the first electrode 210 may be less than or equal to about 2000 μm, and gaps between adjacent finger electrodes 210a may be less than or equal to about 5000 μm. For another example, within the range, the width of each finger electrode 210a of the first electrode 210 may be about 100 nm to about 2000 μm, and gaps between adjacent finger electrodes 210a may be about 10 μm to about 5000 μm.

The second electrode 230 may include, for example, a plurality of finger electrodes 230a and a bus bar electrode 230b connecting the same. The plurality of finger electrodes 230a may be aligned in one direction, without limitation.

Herein, the second electrode 230 may be formed in a size to appropriately control a light shadowing loss and sheet resistance. For example, the second electrode 230 may be designed to have a total area of less than or equal to about 20% relative to the total area of the first photoactive layer 220 and to have power loss of less than or equal to about 20%. For another example, the total area of the second electrode 230 may be about 1 to about 20% relative to the total area of the first photoactive layer 220 and the power loss may be about 0.1 to about 20° A). For example, a width of each finger electrode 230a of the second electrode 230 may be less than or equal to about 2000 μm, and gaps between adjacent finger electrodes 230a may be less than or equal to about 5000 μm. For another example, within the range, the width of each finger electrode 230a of the second electrode 230 may be about 10 nm to about 2000 μm, and gaps between adjacent finger electrodes 230a may be about 1 μm to about 5000 μm.

The first photoactive layer 220 may include a material capable of generating an electron-hole pair using solar energy, for example silicon, a compound semiconductor, an organic semiconductor, a dye, quantum dots, or a combination thereof. The silicon may be, for example, amorphous silicon, the compound semiconductor may be, for example, CIS (Cu—In—Se) or CIGS (Cu—In—Ge—Se), the quantum dots may be, for example, CdS, CdSe, CdTe, ZnS, PbS, InP, InAs, or GaAs, and the organic semiconductor may be, for example, an electron donor and an electron acceptor to form a bulk heterojunction structure.

The electron donor may include, for example, polyaniline, polypyrrole, polythiophene, poly(p-phenylenevinylene), benzodithiophene, thienothiophene, MEH-PPV (poly(2-methoxy-5-(2′-ethyl-hexyloxy)-1,4-phenylene vinylene)), MDMO-PPV (poly(2-methoxy-5-(3,7-dimethyloctyloxy)-1,4-phenylene-vinylene)), pentacene, perylene, poly(3,4-ethylenedioxythiophene) (PEDOT), poly(3-alkylthiophene), polytriphenylamine, phthalocyanine, tin(II) phthalocyanine (SnPc), copper phthalocyanine, triarylamine, benzidine, pyrazoline, styrylamine, hydrazone, carbazole, thiophene, 3,4-ethylenedioxythiophene (EDOT), pyrrole, phenanthrene, tetracene, naphthalene, rubrene, 1,4,5,8-naphthalene-tetracarboxylic dianhydride (NTCDA), poly(3-hexylthiophene) (P3HT), poly((4,8-bis(octyloxy)benzo(1,2-b:4,5-b′)dithiophene)-2,6-diyl-alt-(2-(dodecyloxy)carbonyl)thieno(3,4-b)thiophenediyl)-3,6-diyl (PTB1), poly((4,8-bis(2-ethylhexyloxy)benzo[1,2-b:4,5-b′]dithiophene)-2,6-diyl-alt-(2((2-ethylhexyloxy)carbonyl)-3-fluorothieno[3,4-b]thiophenediyl)-3,6-diyl) (PTB7), a cyclopenta[2,1-b:3,4-b′]dithiophene-based polymer, a silafluorene-based polymer, a carbazole-based compound, a fluorene-based compound, a halogenated fused thiophene, a dithieno[3,2-b:2′3′-d]silole(dithieno[3,2-b:2′3′-d]silole-based compound, and the like, but is not limited thereto.

The electron acceptor may include, for example, fullerene (C60, C70, C74, C76, C78, C82, C84, C720, C860, and the like), a fullerene derivative such as 1-(3-methoxy-carbonyl)propyl-1-phenyl(6,6)C61, C71-PCBM, C84-PCBM, bis-PCBM, and the like, but is not limited thereto.

The front sub-cell SC1 further includes auxiliary layers 205 and 215 positioned under and above first photoactive layer 220. The auxiliary layers 205 and 215 may increase charge mobility and charge selectivity between the first active layer 220 and the first electrode 210, and/or between the first active layer 220 and the second electrode 230, and may be at least one selected from, for example, an electron extraction layer (EEL), a hole extraction layer (HEL), a hole blocking layer (HBL), and an electron blocking layer (EBL), but is not limited thereto. One of the auxiliary layers 205 and 215 may be omitted, and both may be omitted as needed.

The rear sub-cell SC2 is positioned on the opposite side of a solar light incidence side, and includes a third electrode 310, a second photoactive layer 320, and a fourth electrode 330.

One of the third electrode 310 and the fourth electrode 330 may be an anode, and the other may be a cathode.

The third electrode 310 and the fourth electrode 330 may be transparent electrodes, semitransparent electrodes, or opaque electrodes, but at least one of the third electrode 310 and fourth electrode 330 may be a reflection electrode. The reflection electrode may be a metal electrode, for example, aluminum (Al), silver (Ag), copper (Cu), gold (Au), lithium (Li), or an alloy thereof.

The reflection electrode reflects light that is not absorbed in and passes through the first photoactive layer 220 and the second photoactive layer 320 and returns light to the first photoactive layer 220 and the second photoactive layer 320, and accordingly amounts of light absorbed in the first photoactive layer 220 and the second photoactive layer 320 increase and efficiency of a solar cell may be improved. This will be described later.

The third electrode 310 and the fourth electrode 330 may be metal electrodes designed in a form of, for example, a grid pattern.

Third electrode 310 may include, for example, a plurality of finger electrodes 310a and a bus bar electrode 310b connecting the same. The plurality of finger electrodes 310a may be aligned in one direction, without limitation.

The fourth electrode 330 may include, for example, a plurality of finger electrodes 330a and a bus bar electrode 330b connecting the same. The plurality of finger electrode 330a may be aligned in one direction, without limitation.

The second photoactive layer 320 may include a material capable of generating an electron-hole pair with solar energy, for example silicon, a compound semiconductor, an organic semiconductor, a dye, quantum dots, or a combination thereof.

The second photoactive layer 320 may be the same as or different from the first photoactive layer 220.

When the first photoactive layer 220 and the second photoactive layer 320 are the same, light having the same wavelength range may be absorbed and an amount of light increases.

The first photoactive layer 220 and second photoactive layer 320 may absorb light having different wavelength ranges from each other, wherein the light having a different wavelength range may indicate that a difference between a maximum absorption wavelength (λₘₐₓ) of the first photoactive layer 220 and a maximum absorption wavelength (λₘₐₓ) of the second photoactive layer 320 is greater than or equal to about 70 nm. For example, the first photoactive layer 220 may absorb light having a longer wavelength than the second photoactive layer 320. In this way, when the first photoactive layer 220 and the second photoactive layer 320 absorb light having different wavelength ranges from each other, light of a relatively wide wavelength range may be absorbed and thus absorbance increases.

The reflection electrode may reflect light that passes the front sub-cell SC1, the transparent substrate 110, and the rear sub-cell SC2, and return light to the first photoactive layer 220 and the second photoactive layer 320. Accordingly, the amount of light that is absorbed by the first photoactive layer 220 and the second photoactive layer 320 and efficiency of a solar cell may increase.

The reflection electrode is patterned and formed on a part of the second photoactive layer 320, and light transmittance of a solar cell may be controlled according to an area of the reflection electrode.

Since the area of the reflection electrode may be, for example, about 50 to about 95% relative to the total area of the second photoactive layer 320, a highly efficient light transmission type of solar cell controlling greater than or equal to about 5% of light transmittance as well as securing absorbance may be realized. The light transmission type of solar cell may be installed on a window or on an exterior building wall and may perform a function of adjusting inflowing light from the outside, and for example, it may be used as a smart curtain or made into a film attached to glass.

The rear sub-cell SC2 may further include auxiliary layers 305 and 315 beneath and on the second photoactive layer 320. The auxiliary layers 305 and 315 may play a role of increasing charge mobility and charge selectivity between the second active layer 320 and the third electrode 310 and/or between the second active layer 320 and the fourth electrode 330, and for example, may be one selected from an electron extraction layer, a hole extraction layer, a hole blocking layer, and an electron blocking layer, but is the inventive concepts are not limited thereto. One of the auxiliary layers 305 and 315 may be omitted, and both may be omitted as needed.

Total absorbance of the solar cell may be obtained by summing absorbance of the first photoactive layer 220 of the front sub-cell SC1 and absorbance of the second photoactive layer 320 of the rear sub-cell SC2, and total output current of the solar cell may be obtained by summing output current of the front sub-cell SC1 and output current of the rear sub-cell SC2. Unlike the tandem solar cell having a total output current that is determined based on a sub-cell having a low output current among a plurality of sub-cells, the solar cell may accomplish high absorbance, current density, and efficiency.

Accordingly, even when a light transmission type of solar cell is realized by increasing light transmission of the solar cell as aforementioned, the light transmission type of solar cell may secure a higher amount of light than that of a non-light transmission single cell including the first photoactive layer 220 or the second photoactive layer 320 by increasing the amount of light absorbed in the first photoactive layer 220 and the second photoactive layer 320 formed on both sides of the solar cell. Accordingly, the light transmission type of solar cell may be realized without deteriorating absorbance, current density, and efficiency of a solar cell.

In addition, the solar cell according to the example embodiment needs no separate interlayer as a recombination site, compared with a tandem solar cell, and has no structure in which a front sub-cell and a rear sub-cell are sequentially stacked, and thus may decrease performance degradation due to damage to a lower layer during the stacking process, and needs no additional control for matching a current among a plurality of sub-cells.

Hereinbefore, the solar cell including one front sub-cell SC1 and one rear sub-cell SC2 is exemplarily illustrated for better understanding and easy description, but the inventive concepts are not limited thereto, and may be applied to a solar cell including two or more front sub-cells SC1 and/or two or more rear sub-cells SC2 based on a transparent substrate.

Hereinafter, examples and comparative examples are described. However, they are examples, and this disclosure is not limited thereto.

Preparation of Solar Cell

### Example 1

About 30 nm-thick upper and lower auxiliary layers are formed by spin-coating PEDOT:PSS on both sides of a transparent glass substrate. Subsequently, a photoresist having an opening region is disposed as a mask on the upper auxiliary layer, and an upper active layer is formed thereon by applying a solution prepared by dissolving an electron donor (Mₙ=34,000) represented by the following Chemical Formula A and a PC₆₀BM electron acceptor in a ratio of 1:2 (w/w) in chlorobenzene:1,8-diiodooctane (97:3, v/v)

Then, the photoresist is removed, and a metal paste including an aluminum powder and glass frit is screen-printed thereon. Subsequently, another photoresist is disposed on a lower auxiliary layer as a mask, and a lower active layer is formed by applying the mixture. After the photoresist is removed, a metal paste including aluminum powder and glass frit is screen-printed. Herein, a lower anode and a lower cathode are designed to have 95% of the area of the lower active layer. Subsequently, the metal paste is fired at a temperature ranging from 100 to 600° C. to form a metal grid-shaped upper anode and cathode and a lower anode and cathode, manufacturing a solar cell having front and rear sub-cells.

### Example 2

A solar cell is manufactured according to the same method as Example 1, except for designing the lower anode and cathode to have 90% of the area of the lower active layer.

### Example 3

A solar cell is manufactured according to the same method as Example 1, except for designing the lower anode and cathode to have 85% of the area of the lower active layer.

### Example 4

A solar cell is manufactured according to the same method as Example 1, except for designing the lower anode and cathode to have 80% of the area of the lower active layer.

### Example 5

A solar cell is manufactured according to the same method as Example 1, except for designing the lower anode and cathode to have 70% of the area of the lower active layer.

### Example 6

A solar cell is manufactured according to the same method as Example 1, except for designing the lower anode and cathode to have 60% of the area of the lower active layer.

### Example 7

A solar cell is manufactured according to the same method as Example 1, except for designing the lower anode and cathode to have 50% of the area of the lower active layer.

### Comparative Example 1

A solar cell is manufactured according to the same method as Example 1, except for designing the lower anode and cathode to have 40% of the area of the lower active layer.

### Comparative Example 2

A solar cell is manufactured according to the same method as Example 1, except for designing the lower anode and cathode to have 30% of the area of the lower active layer.

### Reference Example 1

An about 30 nm-thick auxiliary layer is formed on one side of a transparent glass substrate by spin-coating PEDOT:PSS. Subsequently, an active layer is formed by disposing a photoresist having an opening region as a mask on the auxiliary layer and applying a solution prepared by dissolving an electron donor (Mₙ=34,000) represented by the above Chemical Formula A and a PC₆₀BM electron acceptor in a ratio of 1:2 (w/w) in chlorobenzene:1,8-diiodooctane (97:3, v/v). Then, a metal paste including an aluminum powder and glass frit is screen-printed on the active layer after removing the photoresist. Subsequently, the metal paste is fired at 110° C. to form an anode and a cathode having a metal grid shape, manufacturing a single non-light transmission solar cell.

### Reference Example 2

A solar cell is manufactured according to the same method as Example 1, except for designing the lower anode and cathode to have 100% of the area of the lower active layer.

### Evaluation

Absorbance and light transmission of the solar cells according to Examples 1 to 7 and Comparative Examples 1 and 2 are evaluated and compared with those of the solar cells according to Reference Examples 1 and 2.

The absorbance is evaluated by radiating light in a wavelength range of about 300 nm to 800 nm with a distance of 1 nm in a transmittance mode by using a UV spectrometer (UV-2450, Dong-II Shimadzu Corp.) based on an assumption that a light loss rate is 5% due to the upper anode and cathode and the lower anode and cathode.

The results are provided in Table 1.

TABLE 1

| | Absorbance | | | | | |
|---|---|---|---|---|---|---|
| | Front sub-cell (front side) | | Rear sub-cell (rear side) | | | |
| | (top cell, cell 1) | | (bottom cell, cell 2) | | | |
| | primary | secondary | primary | secondary | Sum of | Light |
| | absorbance | absorbance | absorbance | absorbance | absorbance | transmission |
| | (%) | (%) | (%) | (%) | (%) | (%) |
| Example 1 | 38.95 | 41.06 | 38.95 | 41.06 | 160.2 | 5 |
| Example 2 | 35.06 | 38.90 | 36.90 | 38.90 | 149.76 | 10 |
| Example 3 | 33.11 | 36.74 | 34.85 | 36.74 | 141.44 | 15 |
| Example 4 | 31.16 | 34.58 | 32.80 | 34.58 | 133.12 | 20 |
| Example 5 | 27.27 | 30.26 | 28.70 | 30.26 | 116.48 | 30 |
| Example 6 | 23.37 | 25.94 | 24.60 | 25.94 | 99.84 | 40 |
| Example 7 | 19.48 | 21.61 | 20.50 | 21.61 | 83.20 | 50 |
| Comparative | 15.58 | 17.29 | 16.40 | 17.29 | 66.56 | 60 |
| Example 1 | | | | | | |
| Comparative | 11.69 | 12.97 | 12.30 | 12.97 | 49.92 | 70 |
| Example 2 | | | | | | |
| Reference | 38.95 | 41.06 | — | — | 80.01 | 0 |
| Example 1 | | | | | | |
| Reference | 38.95 | 43.23 | 38.95 | 43.23 | 164.35 | 0 |
| Example 2 | | | | | | |

In Table 1, when absorbance obtained by summing primary incident light absorbed and passing through a light absorption layer and secondary light reflected by a reflection electrode and absorbed in the light absorption layer is 100%, primary absorbance is the amount of absorbed incident light, and secondary absorbance is the amount of reflected and reabsorbed light.

Referring to Table 1, the solar cells according to Examples 1 to 7 show given (or alternatively, predetermined) light transmission as well as secure similar or higher absorbance than that of a solar cell according to Reference Example 1, that is, a single non-light transmission solar cell. In addition, the light transmission may be adjusted in a range of about 5 to 50% depending on the area of a reflection electrode.

Accordingly, the solar cells according to Examples 1 to 7 may realize a light transmission type solar cell with adjusted light transmission as well as securing absorbance.

While this disclosure has been described in connection with what is presently considered to be practical example embodiments, it is to be understood that the inventive concepts are not limited to the disclosed embodiments, but, on the contrary, is intended to cover various modifications and equivalent arrangements included within the spirit and scope of the appended claims.

What is claimed is:

1. A light transmission type two-sided solar cell comprising:
a front sub-cell on a first side of a transparent substrate, the front sub-cell including a first electrode, a first photoactive layer, and a second electrode; and
a rear sub-cell on a second side of the transparent substrate, the rear sub-cell including a third electrode, a second photoactive layer, and a fourth electrode,
at least one of the third electrode and the fourth electrode being a reflection electrode, the reflection electrode having an area of about 50 to about 95% relative to an area of the second photoactive layer.

2. The light transmission type two-sided solar cell of claim 1, wherein
a total absorbance of the solar cell is a sum of absorbance of the first photoactive layer and absorbance of the second photoactive layer, and
a total absorbance of the solar cell is higher than absorbance of a non-light transmission single sub-cell including one of the first photoactive layer and the second photoactive layer.

3. The light transmission type two-sided solar cell of claim 1, wherein a light transmittance of the solar cell is about 5% to about 50%.

4. The light transmission type two-sided solar cell of claim 1, wherein a total area of one of the first electrode and the second electrode is less than or equal to about 20% relative to a total area of the first photoactive layer.

5. The light transmission type two-sided solar cell of claim 1, wherein the first electrode and the second electrode comprise a plurality of finger electrodes, respectively.

6. The light transmission type two-sided solar cell of claim 5, wherein a width of the finger electrodes of the first electrode is less than or equal to about 2000 μm, and
gaps between adjacent finger electrodes of the first electrode are less than or equal to about 5000 μm.

7. The light transmission type two-sided solar cell of claim 5, wherein
a width of the finger electrodes of the second electrode is less than or equal to about 2000 μm, and
gaps between adjacent finger electrodes of the second electrode are less than or equal to about 5000 μm.

8. The light transmission type two-sided solar cell of claim 1, wherein each of the third electrode and the fourth electrode comprise a plurality of finger electrodes.

9. The light transmission type two-sided solar cell of claim 8, wherein
a width of the finger electrodes of the third electrode is less than or equal to about 2000 μm, and
gaps between adjacent finger electrodes of the third electrode are less than or equal to about 5000 μm.

10. The light transmission type two-sided solar cell of claim 1, wherein each of the first photoactive layer and the second photoactive layer comprise one of silicon, a compound semiconductor, an organic semiconductor, a dye, quantum dots, and a combination thereof.

11. The light transmission type two-sided solar cell of claim 1, wherein the first photoactive layer absorbs light having a longer wavelength range than the second photoactive layer.

12. The light transmission type two-sided solar cell of claim 1, further comprising:
an auxiliary layer between at least one of the first electrode and the first photoactive layer, the second electrode and the first photoactive layer, the third electrode and the second photoactive layer, and the fourth electrode and the second photoactive layer.
